(19) United States
(12) Patent Application Publication
(10) Pub. No.: US 2017/0240418 A1
(43) Pub. Date: Aug. 24, 2017

(54) LOW-COST MINIATURE MEMS VIBRATION SENSOR

(71) Applicant: Knowles Electronics, LLC, Itasca, IL (US)

(72) Inventors: Sarmad Qutub, Des Plaines, IL (US); Martin Volk, Willowbrook, IL (US)

(21) Appl. No.: 15/382,581

(22) Filed: Dec. 16, 2016

Related U.S. Application Data
(60) Provisional application No. 62/296,919, filed on Feb. 18, 2016.

(51) Int. Cl. B81B 7/00; H04R 19/04

(52) U.S. Cl. CPC B81B 7/0041; H04R 19/04; H04R 2201/003

(57) ABSTRACT

A vibrational sensor comprises a microelectromechanical (MEMS) microphone having a base and a lid defining an enclosure, a MEMS acoustic pressure sensor within the enclosure, and a port defining an opening through the enclosure and material that is arranged to plug the port of the MEMS microphone. In embodiments, the MEMS microphone further includes an integrated circuit within the enclosure that is electrically connected to the MEMS acoustic pressure sensor. In some embodiments, the integrated circuit is configured to bias and buffer the MEMS acoustic pressure sensor. In these and other embodiments, the integrated circuit includes circuitry for conditioning and processing electrical signals generated by the MEMS acoustic pressure sensor. In embodiments, the material is arranged with respect to the port so as to cause the MEMS acoustical pressure sensor to sense vibrational energy rather than acoustic energy as in a conventional MEMS microphone.

### CROSS-REFERENCE TO RELATED APPLICATIONS

The present application claims priority to U.S. Provisional Appln. No. 62/296,919 filed Feb. 18, 2016, the contents of which are incorporated herein by reference in their entirety.

### SUMMARY

A vibrational sensor comprises a microelectromechanical (MEMS) microphone having a base and a lid defining an enclosure, a MEMS acoustic pressure sensor within the enclosure, and a port defining an opening through the enclosure and material that is arranged to plug the port of the MEMS microphone. In embodiments, the MEMS microphone further includes an integrated circuit within the enclosure that is electrically connected to the MEMS acoustic pressure sensor. In some embodiments, the integrated circuit is configured to bias and buffer the MEMS acoustic pressure sensor. In these and other embodiments, the integrated circuit includes circuitry for conditioning and processing electrical signals generated by the MEMS acoustic pressure sensor. In embodiments, the material is arranged with respect to the port so as to cause the MEMS acoustical pressure sensor to sense vibrational energy rather than acoustic energy as in a conventional MEMS microphone.

### BRIEF DESCRIPTION OF THE DRAWINGS

The foregoing and other features of the present disclosure will become more fully apparent from the following description and appended claims, taken in conjunction with the accompanying drawings. Understanding that these drawings depict embodiments in accordance with the disclosure and are, therefore, not to be considered limiting of its scope, the disclosure will be described with additional specificity and detail through use of the accompanying drawings.

FIG. 1A shows a representation of an example of a top-port MEMS microphone in accordance with various implementations.

FIG. 1B shows a representation of an example of a bottom-port MEMS microphone in accordance with various implementations.

FIG. 1C shows a representation of an example of a top-port MEMS microphone incorporating an integrated circuit in accordance with various implementations.

FIG. 1D shows a representation of an example of a bottom-port MEMS microphone incorporating an integrated circuit in accordance with various implementations.

FIGS. 2A and 2B illustrate a cross-sectional view and a top view, respectively, of an example top-port MEMS microphone with a first plug in accordance with various implementations.

FIG. 3 illustrates a cross-sectional view of an example top-port MEMS microphone with a second plug in accordance with various implementations.

FIGS. 4A and 4B illustrate a cross-sectional view and a top view, respectively, of an example top-port MEMS microphone with a third plug in accordance with various implementations.

FIG. 5 depicts an example use of embodiments in an example touch sensitive user interface.

FIG. 6 depicts a side view of a portion of an example of a touch sensitive user interface including a common sealing member in accordance with various implementations.

In the following detailed description, reference is made to the accompanying drawings, which form a part hereof. In the drawings, similar symbols identify similar components. The illustrative embodiments described in the detailed description, drawings, and claims are not meant to be limiting. Other embodiments may be used, and other changes may be made, without departing from the spirit or scope of the subject matter presented here. It will be readily understood that the aspects of the present disclosure, as generally described herein, and illustrated in the figures, can be arranged, substituted, combined, and designed in a wide variety of different configurations, all of which are explicitly contemplated and make part of this disclosure.

### DETAILED DESCRIPTION

According to certain general aspects, the present disclosure relates to a new implementation of a vibration sensor. In embodiments, the novel vibration sensor is created by plugging the port (either top or bottom port) of a MEMS microphone, which can be adapted from a conventional MEMS microphone. The MEMS microphone further includes a base, a lid, a MEMS acoustic pressure sensor, and optionally an application specific integrated circuit (ASIC) which provides excitation, and signal buffering required by the MEMS microphone as well as an analog or digital output. By plugging the port of the MEMS microphone, the MEMS acoustic pressure sensor can now be used as an accelerometer. This new device (i.e. plugged MEMS microphone) is low cost, miniature, and light-weight. These features allow the device to be used in existing vibration sensor applications. And new applications are now possible due to its small size, and comparably wide bandwidth for the price. Example additional applications include use in activity sensors, tilt sensors, walking detectors, car/bike other transport motion detectors, elevators, and human motion detectors.

The devices according to the present embodiments have many advantages over existing vibration sensors, such as: (1) they provide a wide usable bandwidth for the cost, so they can be configured as high resonant frequency accelerometers which typically cost several orders of magnitude (e.g. $50.00 vs $0.50) more than the devices of the present embodiments; (2) their light weight and wide bandwidth enable new applications of vibration sensing on small light structures. Compared to a low cost Z-axis CMOS accelerometer having a bandwidth of about 600 Hz, the bandwidth of the devices according to embodiments is approximately 20 KHz; (3) they provide a voltage output, so (a) no special signal conditioning is required, whereas PZT based accelerometers require charge amplifiers, (b) the output has the ability to drive long wires the so devices can be mounted remotely from instrumentation and (c) they can be interfaced to low cost audio ICs and/or equipment; (4) they can provide a digital output so (a) they can be configured with standard audio digital outputs (PDM and I2S) and (b) they can be interfaced to low cost audio ICs and/or equipment; (5) in embodiments including an IC, they can be made with built in signal processing providing (a) customized signal conditioning (filtering, feature extraction, identification) for specific applications and (b) either analog or digital outputs.

The present disclosure describes devices and techniques adapting MEMS microphones for various uses. The MEMS microphones can be commercially available microphones that can function in a conventional manner to detect audio without being adapted according to the embodiments.

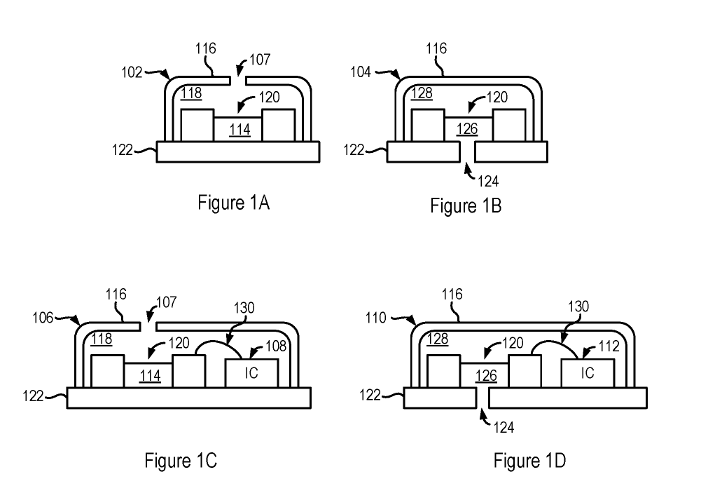

FIGS. 1A-1D depict cross-sectional views of various examples of conventional MEMS microphones that can be adapted for use in the present embodiments. FIG. 1A depicts a cross-sectional view of an example top-port MEMS microphone 102, FIG. 1B depicts a cross-sectional view of an example bottom-port MEMS microphone 104, FIG. 1C depicts a cross-sectional view of an example top-port MEMS microphone 106 including an integrated circuit 108, and FIG. 1D depicts a cross-sectional view of an example bottom-port MEMS microphone 110 with an integrated circuit 112.

Referring to FIG. 1A, the MEMS microphone 102 includes a lid 116 enclosing a MEMS acoustic pressure sensor 120, both of which are disposed over a base 122, the base 122 and lid 116 thereby defining an enclosure. The MEMS acoustic pressure sensor 120 is configured to transform acoustic energy into electrical signals. For example, the MEMS acoustic pressure sensor 120 can include a conductive diaphragm positioned in close proximity to a conductive back-plate. The diaphragm is configured to move in relation to the back-plate in response to incident acoustic energy, where a magnitude of the motion of the diaphragm is, in part, a function of the magnitude of the acoustic energy. The motion of the diaphragm with respect to the back-plate results in a change in a distance between the diaphragm and the back-plate, which, in turn, results in a change in a capacitance between the diaphragm and the back-plate. This change in capacitance can be transformed into a corresponding change in an electrical signal such as a current or a voltage.

The lid 116 includes a port 107, which allows acoustic energy to enter the enclosure through the lid 116. The transducer 120 divides the volume enclosed by the lid 116 into a front volume 118 and a back volume 114. The front volume 118 opens to the outside of the lid 116 through the port 107, and accommodates variations in pressure in accordance with the incident acoustic energy. The back volume 114 is typically an enclosed space defined, in part, by a surface of the diaphragm of the transducer 120 and the base 122. Air in the back volume 114 provides a reference pressure level with respect to which the transducer 120 measures pressure changes resulting from the incident acoustic energy.

In one or more embodiments, the MEMS microphone 102 can have an associated frequency response that describes magnitudes of electrical signals generated at various acoustic energy frequencies. In one or more embodiments, the MEMS microphone 102 exhibits higher sensitivity to acoustic energy in one frequency range than to acoustic energy outside of that frequency range. For example, in one or more embodiments, the MEMS microphone 102 is relatively more sensitive to acoustic energy having frequencies within a particular frequency range centered around its resonance frequency than to acoustic energy having frequencies outside the particular frequency range. In one or more embodiments, the resonance frequency of the MEMS microphone 102 can be a function of one or more factors, such as a ratio of the front volume 118 to the back volume 114, a surface area and/or thickness of the diaphragm of the transducer 120, and a size of the port 107. In one or more embodiments, the MEMS microphone 102 can have a resonance frequency in an ultrasonic frequency range. In any of these embodiments, the frequency range (i.e. bandwidth) of the MEMS microphone 102 can be approximately 20 KHz.

In one or more embodiments, the base 122 may be, or may include, a printed circuit board (e.g. FR4) or a substrate. While not shown in FIG. 1A, in one or more embodiments, the base 122 can provide connectivity by way of interconnects, vias, or conductive traces between the transducer 120 and electronic circuits on or in the base 122.

The bottom-port MEMS microphone 104 shown in FIG. 1B is similar to the top-port MEMS microphone 102 discussed above in relation to FIG. 1A, in that similar to the top-port MEMS microphone 102, the bottom-port MEMS microphone 104 also includes a MEMS acoustic pressure sensor 120, a base 122, and a lid 116. But, unlike the top-port MEMS microphone 102, which includes a port 107 defined by the lid 116, the bottom-port MEMS microphone 104 includes a port 124 defined instead by the base 122. The MEMS acoustic pressure sensor 120 of the bottom-port MEMS microphone 104 divides the volume of the enclosure defined by the lid 116 and base 122 into a front volume 126 and a back volume 128. The front volume 126 opens to the outside of the MEMS microphone 104 through the port 124. The back volume 128 is enclosed by a space defined, in part, by the lid 116 and a surface of the diaphragm of the MEMS acoustic pressure sensor 120. The port 124 allows acoustic energy to enter the front volume 126 and be incident on the MEMS acoustic pressure sensor 120, which transforms the incident acoustic energy into corresponding electrical signals. Similar to the top-port MEMS microphone 102, the bottom-port MEMS microphone 104 also can have an acoustic or mechanical resonance frequency, which can be a function of one or more factors, such as a ratio of the front volume 126 to the back volume 128, a surface area and/or thickness of the diaphragm of the transducer 120, and a size of the port 124. The values of one or more of these factors can be selected to achieve the desired resonance frequency.

The top-port MEMS microphone 106 shown in FIG. 1C is similar to the top-port MEMS microphone 102 shown in FIG. 1A. However, the top-port MEMS microphone 106 shown in FIG. 1C incorporates an integrated circuit (IC) 108 within the same lid 116 that houses the MEMS acoustic pressure sensor 120. In one or more embodiment, such as the one shown in FIG. 1C, the IC 108 can be electrically connected to the MEMS acoustic pressure sensor 120 by at least one bond wire 130. In some other implementations, the IC 108 can be electrically connected to the MEMS acoustic pressure sensor 120 via interconnects, vias, or conductive traces on or within the base 122. The IC 108 can include circuitry for conditioning and processing the electrical signals generated by the MEMS acoustic pressure sensor 120. For example, in one or more embodiments, the IC 108 can include electronic circuits, such as amplifiers, analog-to-digital converters (ADCs), digital-to-analog converters (DACs), filters, level shifters, comparators, modulators, digital logic, and processors.

The bottom-port MEMS microphone 110 shown in FIG. 1D is similar to the bottom-port MEMS microphone 104 discussed above in relation to FIG. 1B. However, the bottom-port MEMS microphone 110 includes an IC 112. The IC 112 is housed in the same lid 116 that houses the MEMS acoustic pressure sensor 120. The IC 112 can be similar to the IC 108 discussed above in relation to FIG. 1C.

It should be noted that, although only one port is shown in each of the examples of FIGS. 1A-1D, this illustration is not limiting and that there can be two or more ports in each of these examples.

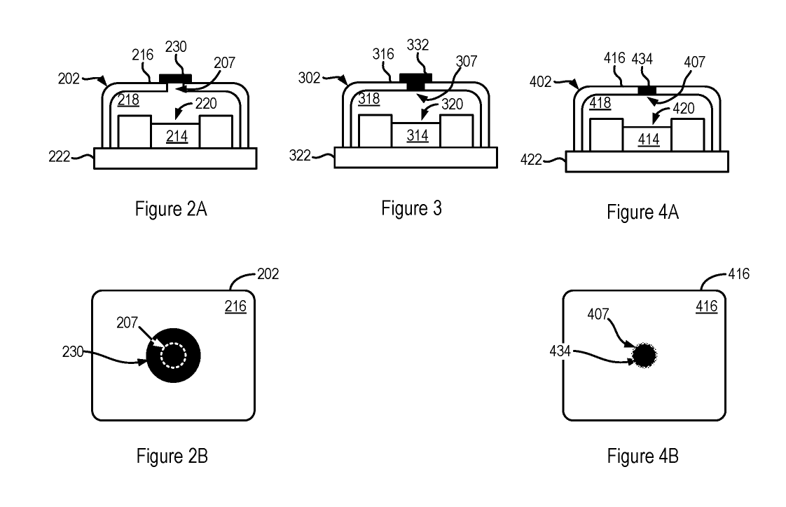

As set forth above, embodiments of the present disclosure relate generally to adapting conventional MEMS microphones for other uses such as vibration sensors by plugging the ports (either top or bottom, and either one or more ports, depending on the configuration). As described in more detail below, FIGS. 2A, 2B, 3, 4A and 4B illustrate examples of embodiments of the present disclosure in which ports of the MEMS microphones are occluded. More particularly, FIGS. 2A and 2B illustrate a cross-sectional view and a top view, respectively, of an example top-port MEMS microphone 202 with a first plug 230. FIG. 3 illustrates a cross-sectional view of an example top-port MEMS microphone 302 with a second plug 332, and FIGS. 4A and 4B illustrate a cross-sectional view and a top view, respectively, of an example top-port MEMS microphone 402 with a third plug 434.

Referring to FIGS. 2A and 2B, the first plug 230 substantially seals the top port 207. The first plug 230 includes a top surface and an opposing bottom surface, where the bottom surface is adhered to a top surface of the lid 216. Moreover, a width of the first plug 230, in a dimension parallel to the top surface of the lid 216 is greater than the width of the top port 207 in the same dimension. In one or more embodiments, the bottom surface of the first plug 230 can be adhered to the top surface of the lid 216 by an adhesive. In one or more embodiments, the top surface of the first plug 230 can include an adhesive to allow the plug along with the MEMS microphone 202 to be attached to a substrate.

It should be noted that elements 214, 218, 220 and 222 in the example of FIG. 2A can be implemented similarly as elements 114, 118, 120 and 122 shown in FIG. 1A and so further details thereof will be omitted here for sake of clarity.

FIG. 3 shows the second plug 332 that substantially seals the top port 307. The second plug 332 is similar to the first plug 230 shown in FIG. 4A, but additionally includes a lower portion to form a “T” shaped cross-section. The lower portion of the second plug 332 lies within the top port 307 and below the plane of the top surface of the lid 316. In one or more embodiments, the lower portion of the second plug 332 can extend beyond a bottom surface of the lid 316 and into the front volume 318. In one or more embodiments, the top surface of the first plug 330 can include an adhesive to allow the second plug 332 along with the MEMS microphone 302 to be attached to a substrate. It should be noted that elements 314, 318, 320 and 322 in the example of FIG. 3 can be implemented similarly as elements 114, 118, 120 and 122 shown in FIG. 1A and so further details thereof will be omitted here for sake of clarity.

Referring to FIG. 4A and 4B, the third plug 434 seals the top port 407 of the MEMS microphone 402. The third port 434 is similar to the second plug 332 shown in FIG. 3 in that like the second plug 332 the third plug 434 also includes a bottom portion. However, unlike the second plug 332, the third plug 434 does not include a top portion. The side walls of the third plug 434 press against the sidewalls of the lid 416 within the port 407 to obstruct and seal the port 407. The top and bottom surface of the third plug 434 may be substantially coplanar with the top and bottom surfaces, respectively, of the lid 416. That is, a thickness of the third plug 434 may be substantially equal to the thickness of the lid 416. In one or more embodiments, the thickness of the third plug 434 can be greater than the thickness of the lid 416. In some other embodiments, the thickness of the third plug 434 can be less than the thickness of the lid 416. In one or more embodiments, an adhesive can be applied to the top surface of the third plug 434 so that the third plug 434 along with the MEMS microphone 402 can be attached to a substrate. It should be noted that elements 414, 418, 420 and 422 in the example of FIG. 4A can be implemented similarly as elements 114, 118, 120 and 122 shown in FIG. 1A and so further details thereof will be omitted here for sake of clarity.

It should be noted that, for ease of illustration, the examples of FIGS. 2A, 2B, 3, 4A and 4B illustrate aspects of adapting a MEMS microphone with a top port and without an ASIC such as the example MEMS microphone 102 shown in FIG. 1A. However, those skilled in the art will understand how to implement the principles of the invention using other MEMS microphones, including those shown in FIGS. 1B, 1C and 1D after being taught by the present examples.

More particularly, the present embodiments include MEMS microphones adapted as illustrated above and including an ASIC for biasing and buffering the MEMS acoustic pressure sensor 220, 320 and 420, and to condition and process electrical signals generated by the MEMS acoustic pressure sensor 220, 320 and 420. This can include processing the signals so as to generate one or more of a digital PDM electrical output, a digital I2S electrical output, an analog differential electrical output, and an output that is compatible with audio CODECs and/or digital signal processor (DSP) inputs for low cost direct interfacing. In other embodiments, the ASIC can be configured to perform built in signal processing. It should be noted that a vibration sensor according to these and other embodiments does not require an external charge amplifier, bridge circuit, or a current source for an electrical interface, as would be required by vibration sensors implemented using PZT's for example.

As discussed above, the vibration sensor according to the embodiments allows for new uses of such devices.

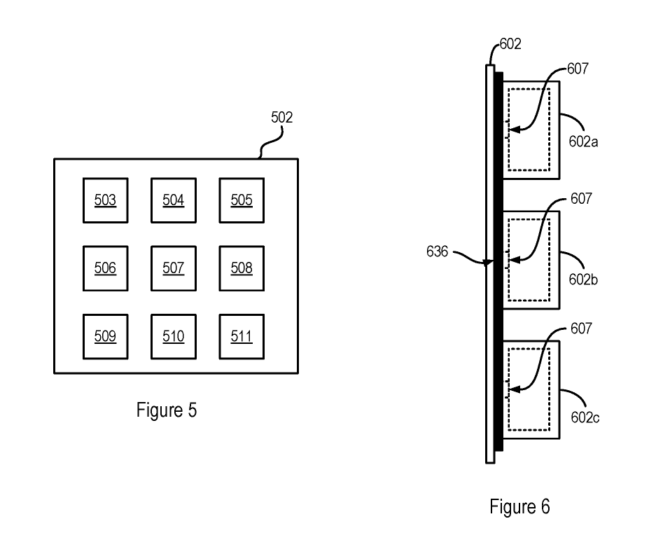

FIG. 5 depicts an example embodiment where MEMS microphones have been adapted according to the present embodiments for detecting vibrations in a touch sensitive interface on a front surface of a substrate 502. The front surface of the substrate 502 provides several button representations 503-511. The substrate 502 may be a generally flat and planar object or structure (such as a metal plate, panel, platen or a (part of a) screen), although the substrate 502 may exhibit a curvature at one or more edges, at one or more portions of the substrate 502, or generally across an entirety of the substrate 502. In some embodiments, the substrate 502 is used on or in a user interface for a home appliance or consumer electronics device (e.g., a refrigerator, washing machine, oven, cellular phone, tablet, or personal computer). In one or more embodiments, the substrate 502 may be formed of one or more layers of metal (e.g., stainless steel), glass, plastic, or a combination of these materials.

A user can press or tap, such as with finger (or fingers) or some other object, the front surface of the substrate 502 over the button representations 503-511 to enter an input. The user's pressing on the substrate 502 can cause vibrations in the substrate. The vibrations may be in any frequency range detectable by the MEMS microphone, such as, for example, subsonic, acoustic, or ultrasonic.

FIG. 6 depicts a side view of a portion of an example of a touch sensitive user interface including the substrate 502 shown in FIG. 5 and several MEMS microphones (e.g., MEMS microphones 602a, 602b and 602c) attached to the rear surface of the substrate 502. In one or more embodiments, the MEMS microphones are attached to the side of the substrate that is opposite to the side on which the button representations 503-511 are provided. For example, the MEMS microphones 602a, 602b and 602c can correspond to button representations 503, 506, and 509, respectively, shown in FIG. 5. In one or more embodiment, more than one MEMS microphone may correspond to each button representation.

FIG. 6 shows a common sealing member 636 that seals the ports of the MEMS microphones (e.g., the three MEMS microphones 602a-602c). In one or more embodiments, the common sealing member 636 can be a substantially planar sheet that has a first side and an opposing second side. The first side can be attached to, and cover the ports 607 of at least two MEMS microphones, and the second side can be attached to the substrate 602 with, for example, and adhesive. In some embodiments, the common sealing member 636 may be an adhesive sheet. In one or more embodiments, the first side can include a matrix of raised portions or plugs to which the ports of the MEMS microphones can be attached to seal the ports.

Any one of the MEMS microphones discussed above in relation to FIGS. 1A to 1D, as adapted as described in connection with the examples of FIGS. 2A, 2B, 3, 4A and 4B, can be used to implement the MEMS microphones 602a, 602b and 602c shown in FIG. 6. For example, if the top-port MEMS microphones 102 or 106 (FIGS. 1A and 1C, respectively) were used to implement the MEMS microphone 602a shown in FIG. 6, then the common sealing member 636 can be coupled to the lid 116 of the top-port MEMS microphones 102 or 106; similarly, if the bottom-port MEMS microphone 104 or 110 (FIGS. 1B and 1D, respectively) were used to implement the MEMS microphone 602a shown in FIG. 6, then the common sealing member 636 can be coupled to the base 122 of the bottom-port MEMS microphone 104 or 110.

Depending on the type of MEMS microphone used to implement MEMS microphones 602a, 602b and 602c, one or more of the first plug 230 described in connection with the example of FIGS. 2A and 2B, the second plug 332 described in connection with the example of FIG. 3, the third plug 434 described in connection with the example of FIGS. 4A and 4B and the common sealing member 636 can be formed of materials such as plastic, rubber, wood, or metal.

As described above, the resonance frequency of any of the MEMS microphones shown in FIGS. 1A-1D used to implement the MEMS microphones 602a, 602b and 602c can be a function of one or more factors, such as a ratio of the front volume 118 to the back volume 114, a surface area and/or thickness of the diaphragm of the transducer 120, and a size of the port 107. In one or more embodiments, values of one or more of these factors can be selected such that the resonance frequencies of the MEMS microphones 602a, 602b and 602c are substantially within a range of frequencies of acoustic energy resulting from the vibrations, such as vibrations caused by touching the substrate 502 (shown in FIGS. 5 and 6). However, a MEMS microphone may detect vibrations propagating through the substrate 502 rather than propagating through air, and thus an acoustic nature of the vibrations is not necessary. Accordingly, a mechanical resonance frequency of the MEMS microphone may be designed. It is to be understood that in some embodiments, acoustic or mechanical resonances may be at frequencies outside of expected vibration frequencies ranges related to user input.

Additional aspects of incorporating vibrational sensors according to the present embodiments in a touch sensitive device are set forth in co-pending U.S. Application No. [K-0256], the contents of which are incorporated herein by reference in their entirety.

The herein described subject matter sometimes illustrates different components contained within, or connected with, different other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality, and any two components capable of being so associated can also be viewed as being “operably couplable,” to each other to achieve the desired functionality. Specific examples of operably couplable include but are not limited to physically mateable and/or physically interacting components and/or wirelessly interactable and/or wirelessly interacting components and/or logically interacting and/or logically interactable components.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.).

It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations).

Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.” Further, unless otherwise noted, the use of the words “approximate,” “about,” “around,” “substantially,” etc., mean plus or minus ten percent.

The foregoing description of illustrative embodiments has been presented for purposes of illustration and of description. It is not intended to be exhaustive or limiting with respect to the precise form disclosed, and modifications and variations are possible in light of the above teachings or may be acquired from practice of the disclosed embodiments. It is intended that the scope of the invention be defined by the claims appended hereto and their equivalents.

What is claimed is:

1. A vibrational sensor, comprising:
a microelectromechanical (MEMS) microphone having a base and a lid defining an enclosure, a MEMS acoustic pressure sensor within the enclosure, and a port defining an opening through the enclosure; and
material that is arranged to plug the port of the MEMS microphone.

2. The vibrational sensor of claim 1, wherein the material completely plugs the port.

3. The vibrational sensor of claim 2, wherein the opening in the enclosure defined by the port has a width, the material having a width that is greater than the width of the opening so as to completely cover the opening and thereby plug the port.

4. The vibrational sensor of claim 2, wherein the opening in the enclosure defined by the port has a width, the material completely filling the width of the opening.

5. The vibrational sensor of claim 2, wherein the opening in the enclosure defined by the port has a width, the material having a top portion with a width that is greater than the width of the opening, and a bottom portion that completely fills the width of the opening.

6. The vibrational sensor of claim 1, wherein the port defines the opening in the base of the MEMS microphone.

7. The vibrational sensor of claim 1, wherein the port defines the opening in the lid of the MEMS microphone.

8. The vibrational sensor of claim 1, wherein the material comprises an adhesive.

9. The vibrational sensor of claim 1, wherein the MEMS microphone further includes an integrated circuit within the enclosure that is electrically connected to the MEMS acoustic pressure sensor.

10. The vibrational sensor of claim 9, wherein the integrated circuit is configured to buffer the MEMS acoustic pressure sensor.

11. The vibrational sensor of claim 9, wherein the integrated circuit includes circuitry for conditioning and processing electrical signals generated by the MEMS acoustic pressure sensor.

12. The vibrational sensor of claim 11, wherein the conditioning and processing includes generating a digital PDM electrical output.

13. The vibrational sensor of claim 11, wherein the conditioning and processing includes generating a digital I2S electrical output.

14. The vibrational sensor of claim 11, wherein the conditioning and processing includes generating an analog differential electrical output.

15. The vibrational sensor of claim 11, wherein the conditioning and processing includes generating an electrical output is compatible with audio CODECs and/or digital signal processor (DSP) inputs.

16. The vibrational sensor of claim 1, wherein the material is arranged with respect to the port so as to cause the MEMS acoustical pressure sensor to sense vibrational energy rather than acoustic energy.

17. The vibrational sensor of claim 16, wherein the MEMS microphone is attached to a rear surface of a substrate.

18. The vibrational sensor of claim 17, wherein the material is arranged such that energy from vibrations from a front surface of the substrate propagate to the MEMS acoustic pressure sensor of the MEMS microphone.

19. The vibrational sensor of claim 1, further comprising a second port defining a second opening through the enclosure, and second material that is arranged to plug the second port of the MEMS microphone.
